(19) United States
(12) Patent Application Publication
(10) Pub. No.: US 2025/0157898 A1
(43) Pub. Date: May 15, 2025

(54) FLIP CHIP QUAD FLAT NO LEADS (QFN) PACKAGE

(71) Applicant: STMicroelectronics International N.V., Geneva (CH)

(72) Inventor: Venero SANTAMARIA, Belpasso (IT)

(73) Assignee: STMicroelectronics International N.V., Geneva (CH)

(21) Appl. No.: 18/389,257

(22) Filed: Nov. 14, 2023

(51) Int. Cl. H01L 23/495; H01L 23/00; H01L 23/31

(52) U.S. Cl. CPC H01L 23/49582; H01L 23/3107; H01L 23/49558; H01L 24/13; H01L 24/16; H01L 24/17; H01L 2224/1357; H01L 2224/16245; H01L 2224/1703; H01L 2924/381

(57) ABSTRACT

A leadframe includes first leads and second leads, wherein each lead of the first and second leads has an upper surface. First and second silver spots are provided on the upper surface of each lead of the first and second leads. An integrated circuit die has a front surface including first and second interconnection pads. A first pillar is mounted to each first interconnection pad, and second pillar is mounted to each second interconnection pad. The integrated circuit die is mounted in flip chip orientation to the leadframe with the first pillars soldered to the first silver spots and the second pillars soldered to the second silver spots. A resin body encapsulates the integrated circuit die mounted to the leadframe.

### TECHNICAL FIELD

The present disclosure generally concerns packages for integrated circuit devices and, in particular, a quad flat no leads (QFN) package supporting an integrated circuit die with different sized pillar bumps mounted to a leadframe in flip chip orientation.

### BACKGROUND

Semiconductor fabrication techniques are used to form multiple integrated circuits on a wafer of semiconductor material using well known front end of line (FEOL) and back end of line (BEOL) processes. Once the wafer of semiconductor material is processed to a complete stage, a singulation process is used to dice the processed wafer into individual integrated circuit devices (each such device also referred to in the art as an integrated circuit (IC) die). Each individual integrated circuit device is then packaged by attaching the IC die to a leadframe and then encapsulating the IC die and leadframe in a resin body.

Different types of packages are known in the art. Of particular interest is the quad flat no leads (QFN) package which is well suited for surface mount installation. The QFN package has a small square or rectangular resin body with no leads. In this context, “no leads” means that the electrode contacts for the packaged device do not extend away from the resin body.

FIG. 1 illustrates a cross-sectional view of a conventional QFN packaged integrated circuit device 10. The leadframe 12 includes a die pad 12a and plurality of leads 12b arranged around the die pad. The back surface of the integrated circuit die 14 is mounted to the upper surface of the die pad 12a using a die attach material (for example, a die attach film (DAF), other adhesive, or soldering—not explicitly shown). The front surface of the integrated circuit die 14 includes interconnection pads 16 arranged, generally speaking, adjacent the peripheral edge of the die. These interconnection pads 16 are electrically connected through an interconnection network (comprising, for example, a redistribution layer (RDL) and metallization levels) to the circuits that are integrated on the semiconductor substrate of the die. Electrical connection of the interconnection pads 16 to the leads 12b is made through bonding wires 18. The integrated circuit die 14 mounted to the die pad 12a and electrically connected to the leads 12b is then encapsulated in a resin body 20. The bottom surface of the die pad 12a is exposed at the bottom surface of the resin body (for example, for use as a thermal conductor or heat sink). Additionally, the bottom surfaces of the leads 12b are exposed at the bottom surface of the resin body and the side surfaces of the leads 12b are exposed at the sides of the resin body to support surface mount attachment of the packaged IC die to a support substrate such as a printed circuit board (PCB).

### SUMMARY

In an embodiment, an integrated circuit package comprises: a leadframe including a first plurality of leads and a second plurality of leads, wherein each lead of the first and second plurality of leads has an upper surface; at least one first silver spot on the upper surface of each lead of the first plurality of leads, wherein each first silver spot has a first size and first shape in plan; at least one second silver spot on the upper surface of each lead of the second plurality of leads, wherein each second silver spot has a second size and second shape in plan; an integrated circuit die having a front surface including a first plurality of interconnection pads and a second plurality of interconnection pads; a first pillar mounted to each interconnection pad of the first plurality of interconnection pads, wherein the first pillar has a third size and third shape in plan; a second pillar mounted to each interconnection pad of the second plurality of interconnection pads, wherein the second pillar has a fourth size and fourth shape in plan; wherein the integrated circuit die is mounted in flip chip orientation to the leadframe with the first pillars soldered to the first silver spots and the second pillars soldered to the second silver spots; and a resin body encapsulating the integrated circuit die mounted to the leadframe.

In an embodiment, a layer of non-solder wettable material (such as, for example, an oxide) is present on the upper surface of each lead of the first and second plurality of leads, said layer of non-solder wettable material surrounding the first and second silver spots.

In an embodiment, the first and second plurality of leads provide electrode contacts for a flat no leads type package.

### BRIEF DESCRIPTION OF THE DRAWINGS

The foregoing and other features and advantages will be discussed in detail in the following non-limiting description of specific embodiments in connection with the accompanying drawings, in which:

FIG. 1 illustrates a cross-sectional view of a conventional QFN packaged integrated circuit device;

FIG. 2 illustrates a cross-sectional view of a QFN packaged integrated circuit device with a flip chip die;

FIG. 3A illustrates a perspective view of a die using non-uniformly sized pillars;

FIGS. 3B and 3C show side views of pillars having different sizes;

FIG. 4 illustrates a perspective view of a leadframe;

FIGS. 5A and 5B illustrate, in plan view, a comparison of pillar and silver plated spot sizes and shapes;

FIGS. 5C and 5D illustrate, in plan view, a comparison of pillar and silver plated spot sizes and shapes;

FIG. 6 illustrates a phantom perspective view of a QFN packaged integrated circuit device using the die of FIG. 3A attached in flip chip to the leadframe of FIG. 4;

FIG. 7 illustrates a cross-section through the connection of a die pillar to a lead of the leadframe; and

FIGS. 8A, 8B and 8C show cross section images of the integrated circuit device.

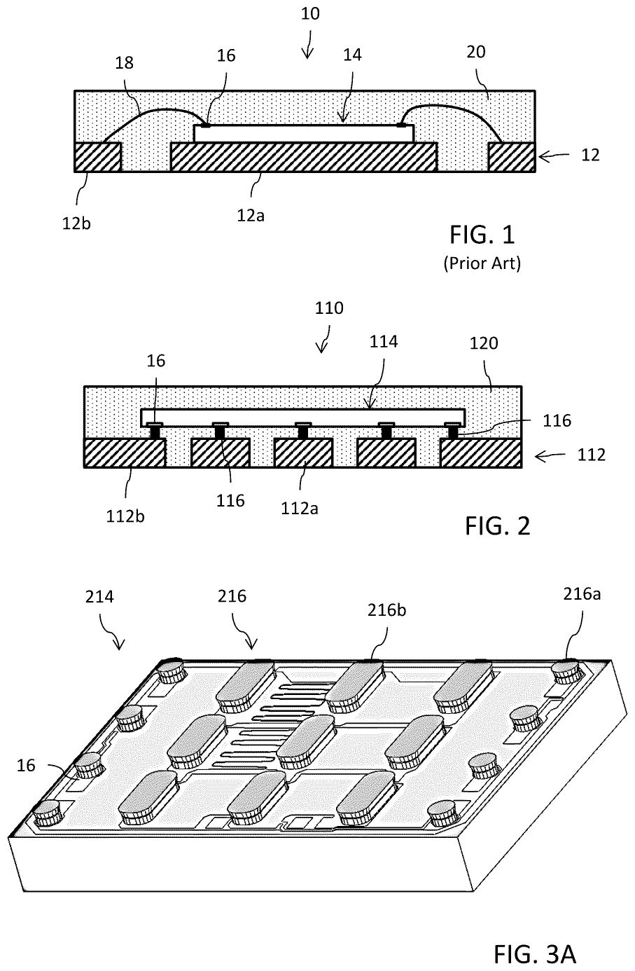

### DETAILED DESCRIPTION

The same elements have been designated with the same reference numerals in the different drawings. In particular, the structural and/or functional elements common to the different embodiments may be designated with the same reference numerals and may have identical structural, dimensional, and material properties.

Throughout the present disclosure, the term “connected” is used to designate a direct electrical connection between circuit elements with no intermediate elements other than conductors, whereas the term “coupled” is used to designate an electrical connection between circuit elements that may be direct, or may be via one or more intermediate elements.

The terms “about”, “substantially”, and “approximately” are used herein to designate a tolerance of plus or minus 10%, preferably of plus or minus 5%, of the value in question.

Reference is now made to FIG. 2 which illustrates a cross-sectional view of a QFN packaged integrated circuit device 110 with a flip chip die. The leadframe 112 includes a plurality of first (finger or segment) leads 112a and plurality of second (end) leads 112b. The front surface of the integrated circuit die 114 includes die pillars 116 (also referred to in the art as bumps) mounted to interconnection pads 16. The interconnection pads 16 are electrically connected through an interconnection network (comprising, for example, a redistribution layer (RDL) and metallization levels) to the circuits that are integrated on the semiconductor substrate of the die. The integrated circuit die 114 is mounted to the leadframe in “flip chip” orientation with the front surface of the integrated circuit die 114 facing the upper surface of the leadframe 112. The distal ends of the die pillars 116 are soldered to the upper surface of the leadframe. Specifically, the ends of the die pillars 116 arranged adjacent the peripheral edge of the die are soldered to the second leads 112b and the die pillars 116 arranged more centrally on the die are soldered to the first leads 112a. The integrated circuit die 114 mounted in flip chip orientation to the leadframe is then encapsulated in a resin body 120 to form a packaged IC die. The bottom surfaces of the leads 112a are exposed at the bottom surface of the resin body and the end surfaces of the leads 112a are exposed at the sides of the resin body. Additionally, the bottom surfaces of the leads 112b are exposed at the bottom surface of the resin body and the side surfaces of the leads 112b are exposed at the sides of the resin body.

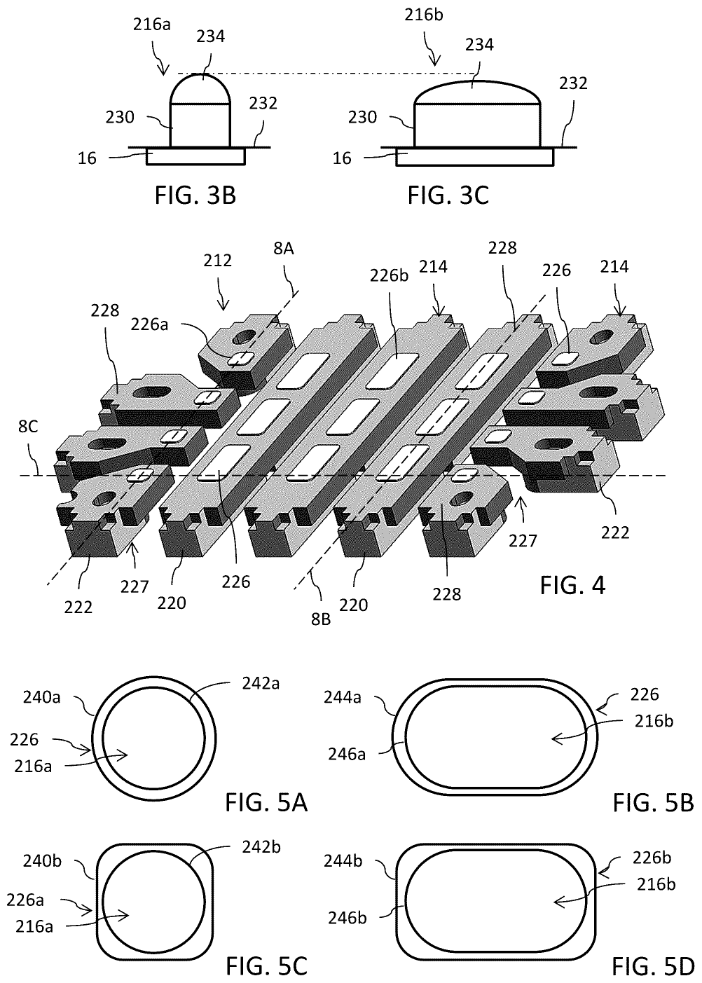

An integrated circuit die may be designed to use die pillars of different sizes. FIG. 3A illustrates a perspective view of an integrated circuit die 214 using non-uniform sized pillars 216. The pillars 216 may include, for example, a pillar 216a having a first size and shape (illustrated here with a round shape in plan (i.e., top facing) view having a first surface area) and a pillar 216b having a second size and shape (illustrated here with a stadium or running track or ovular shape in plan (i.e., top facing) view having a second surface area that is larger than the first surface area). The pillars 216a having the first size and shape are arranged adjacent the peripheral edge of the die, while the pillars 216b having the second size and shape are arranged more centrally on the die. This arrangement is by example only, without limitation, and the designer may provide pillars of different size and shape at desired locations. Furthermore, while die 214 is illustrate with pillars of two different shapes in plan, it will be understood that the integrated circuit die may be designed to use die pillars of many different shapes and sizes (for example, three or more pillars of different size and shape may be included). As an example, without limitation, first pillars of a stadium or running track or ovular shape in plan view, second pillars of a round shape in plan view having a first surface area, and third pillars of a round shape in plan view having a second surface area, which is smaller than the first surface area, can be included on a single die 214.

FIG. 3B shows a side view of the pillar 216a and FIG. 3C shows a side view of the pillar 216b. Each pillar 216 includes a base 230 made of copper mounted to the surface 232 of the interconnection pad 16 of the integrated circuit device. The base 230 is topped with solder 234. A thin layer of nickel may be provided between the solder 234 and the top of the base 230. Considering pillar growth is made by an electroplating process, having pillars of different shape means that there will different plating areas to cover, combined with process variability, and this may result in poor pillar coplanarity which can have a consequent impact of soldering quality between the pillars and the leadframe. Note the topological difference in pillar height, indicated by the dotted line. This topological difference can be a concern when mounting the integrated circuit die 214 in flip chip to a leadframe due to the enhanced risk of forming a cold joint between the pillar 216a, pillar 216b and the leadframe. To reduce this risk, it is proposed to form a silver spot on the leadframe surrounded by a non-wetting layer. Both will work to enhance the solder joint between the pillars 216a, 216b and the leadframe

Reference is now made to FIG. 4 which illustrates a perspective view of a leadframe 212. The leadframe 212 is made from a sheet of copper or copper-alloy, for example, that has been shaped by manufacturing processes such as stamping and etching to define a plurality of leads 214. The leads 214 may comprise a plurality of segment (or finger) leads 220 and a plurality of end leads 222. The segment leads 220 and end leads 222 may have a half-etched configuration as is known in the art to form undercut regions 227. It will be noted that for simplicity the illustration in FIG. 4 shows the leadframe 212 in the context of a single package.

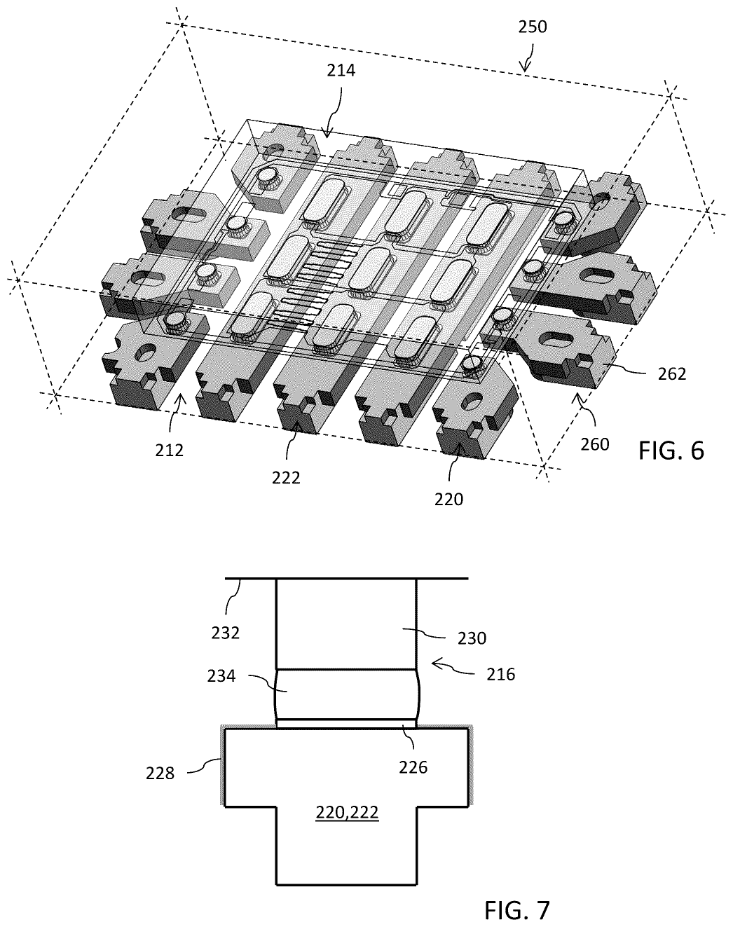

Each segment lead 220 extends longitudinally (i.e., in their longer or length direction) in a first direction and, as shown in FIG. 6, extends between opposed first and second sides of the package (those first sides being perpendicular to the first direction). Longitudinal end surfaces of each segment lead 220 are exposed from the package at the first and second sides of the package.

The end leads 222 are arranged in two groups. A first group is located laterally (i.e., in width direction) on one side of the segment leads 220 and a second group is located laterally (i.e., in width direction) on an opposed side of the segment leads 220. Certain ones of the end leads 222 have end surfaces exposed from the package at the first and second sides of the package. Other ones of the end leads 222 have end surfaces exposed from the package at third and fourth sides of the package which extend perpendicular to the first and second sides of the package.

Spots 226 of silver are plated at specific locations on the upper surfaces of the segment leads 220 and end leads 222. A photomask may be deposited on the surface of the leadframe leads 220, 222 and patterned to include openings at the desired locations for spots 226. An electrolytic growth process is then performed to plate the surface of the leadframe leads 220, 222 at the openings in the photomask and form the spots 226. The silver spots 226 may have a thickness, for example, in a range of 2.5 to 7.25 μm. The portions of the upper surfaces of the segment leads 220 and end leads 222 which are not covered by the silver plated spots 226 are coated with a non-solder wetting layer 228. As an example, the layer 228 may comprise a thin brown oxide layer. The oxide layer may have a thickness, for example, in a range of 10-100 nanometers. This brown oxide layer may be formed, by example, through a thermal oxidation process, chemical process, or electrochemical process. Prior to performing the process for forming the non-solder wetting layer 228, the leadframe may be subjected to a fine etching process to provide a surface roughness in support of improving better molding mater adhesion to the leadframe.

The process for oxidation to form the layer 228 as a brown oxide layer may comprise, for example, a chemical interaction where the leadframe is placed in a chemical bath where the chemical reacts with the copper but does not react with the silver plated spots 226. Other surfaces of the leadframe where no oxidation layer is desired may be covered by a mask before performing the chemical interaction.

Other processes may be used for passivation of the leadframe to obtain the non-solder wetting layer 228. Such processes include, for example, chemical processes, heating processes and sputtering processes.

The locations of the silver plated spots 226 on the upper surfaces of the segment leads 220 and end leads 222 correspond to (i.e., are aligned or coincide with) the locations of the pillars 216a, 216b when the integrated circuit die 214 is oriented in flip chip configuration and mounted to the leadframe 212 as shown in FIGS. 6 and 7. The size and shape of the silver plated spots 226 generally correspond to the size and shape of the pillars 216a, 216b, such that during solder reflow the solder material (Ag+Tin alloy, for example) melts and assumes the shape of the silver spot. In a preferred implementation, the spots 226 are slightly larger in area than the corresponding pillar in order to account for manufacturing and assembly tolerances. In particular, the size and shape of the silver plated spots 226 corresponds to the size and shape of the pillars 216a, 216b as shown in FIGS. 5A and 5B (round 240a and round 242a, and ovular 244a and ovular 246a, for example). Alternatively, the size and shape of the silver plated spots 226 can be slightly different than the size and shape of the pillars 216a, 216b. For example, as shown in FIG. 5C, there are silver plated spots 226a having a square shape with rounded corners (reference 240b) in plan view with the pillars 216a having a round shape (reference 242b) in plan view. As another example, as shown in FIG. 5D, there are silver plated spots 226b having a rectangular shape with rounded corners (reference 244b) in plan view with the pillars 216b having a stadium or running track or ovular shape (reference 246b) in plan view.

FIG. 6 further shows with the dotted lines the general outline of the resin body 250 which encapsulates the integrated circuit die 214 mounted in flip chip to the leadframe 212. The bottom surfaces 260 of the segment leads 220 and end leads 222 are exposed at the bottom surface of the resin body. Furthermore, side edges 262 of the segment leads 220 and end leads 222 are exposed at the sides of the resin body.

FIG. 7 illustrates a cross-section through the connection of a pillar 216 to a lead 220, 222 of the leadframe. Each silver plated spot 226 surrounded by the non-solder wetting layer 228 reduces bleed of the solder 234 during reflow. Each silver plated spot 226 further improves to formation of a solder joint between the pillar 216 and the leadframe.

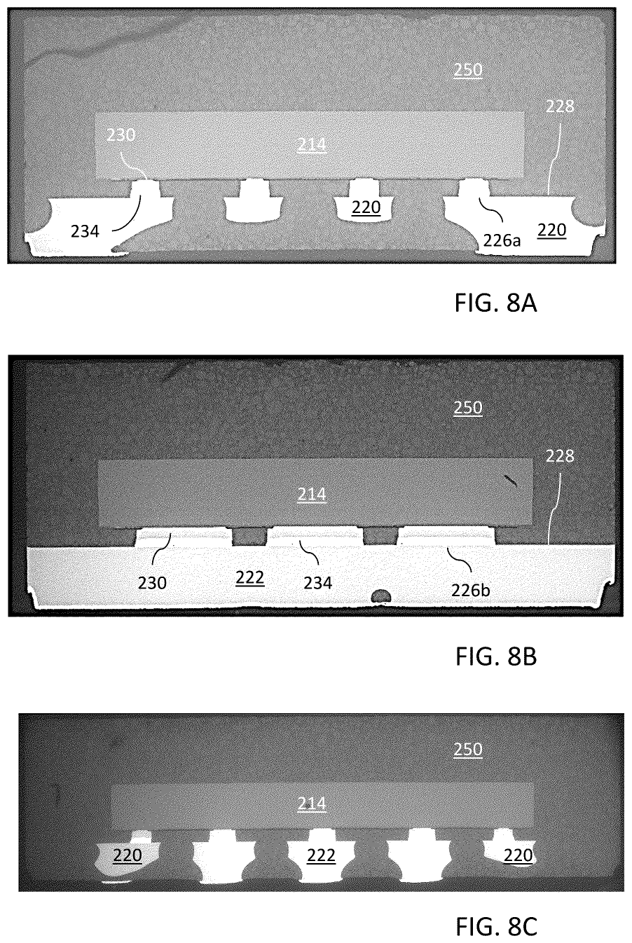

FIGS. 8A, 8B and 8C show cross section images of the integrated circuit device taken along dotted lines 8A, 8B and 8C, respectively, in FIG. 4. As shown, the constraint on solder bleed provided through the use of the silver plated spots 226 and non-solder wetting layer 228 enables a reduction in pillar pitch distance so that are larger number of pillars can be accommodated in the die design without having to increase die or overall package size.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

1. An integrated circuit package, comprising:
a leadframe including a first plurality of leads and a second plurality of leads, wherein each lead of the first and second plurality of leads has an upper surface;
at least one first silver spot on the upper surface of each lead of the first plurality of leads, wherein each first silver spot has a first size and first shape in plan;
at least one second silver spot on the upper surface of each lead of the second plurality of leads, wherein each second silver spot has a second size and second shape in plan;
an integrated circuit die having a front surface including a first plurality of interconnection pads and a second plurality of interconnection pads;
a first pillar mounted to each interconnection pad of the first plurality of interconnection pads, wherein the first pillar has a third size and third shape in plan;
a second pillar mounted to each interconnection pad of the second plurality of interconnection pads, wherein the second pillar has a fourth size and fourth shape in plan;
wherein the integrated circuit die is mounted in flip chip orientation to the leadframe with the first pillars soldered to the first silver spots and the second pillars soldered to the second silver spots; and
a resin body encapsulating the integrated circuit die mounted to the leadframe.

2. The integrated circuit package of claim 1, further comprising a non-solder wetting layer on the upper surface of each lead of the first and second plurality of leads, said non-solder wetting layer surrounding the first and second silver spots.

3. The integrated circuit package of claim 2, wherein said non-solder wetting layer is an oxide layer.

4. The integrated circuit package of claim 3, wherein said oxide layer is a brown oxide layer.

5. The integrated circuit package of claim 2, wherein said non-solder wetting layer is formed using at least one of a chemical process, a heating process and a sputtering process.

6. The integrated circuit package of claim 1, wherein the first plurality of leads provide electrode contacts at a side and bottom of the resin body for a flat no leads type package.

7. The integrated circuit package of claim 1, wherein the second plurality of leads provide electrode contacts at a side and bottom of the resin body for a flat no leads type package.

8. The integrated circuit package of claim 1, wherein the first size is larger than the third size and the first shape and third shape are the same.

9. The integrated circuit package of claim 1, wherein the first size is larger than the third size and the first shape and third shape are not the same.

10. The integrated circuit package of claim 1, wherein the second size is larger than the fourth size and the second shape and fourth shape are the same.

11. The integrated circuit package of claim 1, wherein the second size is larger than the fourth size and the second shape and fourth shape are not the same.

12. The integrated circuit package of claim 1, wherein the second plurality of leads comprise segment leads extending longitudinally in a first direction between opposed first and second sides of the resin body, wherein the first and second sides extend in a second direction perpendicular to the first direction.

13. The integrated circuit package of claim 12, wherein the resin body further includes opposed third and fourth sides extending in the first direction, and wherein the first plurality of leads comprise end leads arranged in two groups with a first one of said two groups arranged along the third side and a second one of said two groups arranged along the fourth side.

14. The integrated circuit package of claim 13, wherein end surfaces of the segment leads are exposed from the resin body at the first and second sides, and wherein end surfaces of the end leads are exposed from the resin body at the third and fourth sides.

15. The integrated circuit package of claim 14, wherein end surfaces of some of the end leads are exposed from the resin body at the first and second sides.

16. The integrated circuit package of claim 1, wherein then integrated circuit die further includes a third plurality of interconnection pads on the front surface, and further comprising a third pillar mounted to each interconnection pad of the third plurality of interconnection pads, wherein at least one of a size and a shape of the third pillar is different from a corresponding size and shape of each of the first and second pillars.
